(19) United States
(12) Patent Application Publication
(10) Pub. No.: US 2019/0371681 A1
(43) Pub. Date: Dec. 5, 2019

(54) STACKED WAFER INTEGRATED CIRCUIT

(71) Applicant: Synaptics Incorporated, San Jose, CA (US)

(72) Inventor: Stephen L. MOREIN, San Jose, CA (US)

(21) Appl. No.: 16/120,166

(22) Filed: Aug. 31, 2018

Related U.S. Application Data
(60) Provisional application No. 62/679,677, filed on Jun. 1, 2018.

(51) Int. Cl. H01L 21/8238; H01L 21/762; H01L 21/304; H01L 25/18

(52) U.S. Cl. CPC H01L 21/823878; H01L 21/76224; H01L 25/18; H01L 21/304; H01L 21/823892

(57) ABSTRACT

A method for manufacturing a stacked wafer integrated circuit (IC) device. The method is performed by fabricating first circuitry on a top surface of a first IC wafer and depositing one or more electrical insulators, between the first circuitry, through a depth of the first IC wafer such that the one or more electrical insulators are not exposed on a bottom surface of the first IC wafer. Layers of semiconductor substrate are subsequently removed from a bottom surface of the first IC wafer until the one or more electrical insulators become exposed on the bottom surface of the first IC wafer.

### CROSS-REFERENCE TO RELATED APPLICATION

This application claims priority and benefit under 35 USC § 119(e) to U.S. Provisional Patent Application No. 62/679,677, filed on Jun. 1, 2018, which is incorporated herein by reference in its entirety.

### TECHNICAL FIELD

The present embodiments relate generally to integrated circuit (IC) devices, and specifically to stacked-wafer IC devices.

### BACKGROUND OF RELATED ART

Semiconductor devices can be broadly categorized into two types: digital and analog. Analog devices may directly measure and/or manipulate the precise electrical properties (e.g., voltages) of real-world signals. For example, a touch sensor may detect objects in contact with and/or proximate to an input surface based on changes in a sensing signal (or electric field) measured at the input surface. The sensor may measure the exact amplitude of the sensing signal to determine the proximity of the object to the input surface. In contrast, digital devices are merely concerned with the presence or absence of a signal, rather than the precise amplitude of the signal. For example, a display driver may process image data to determine which pixels of a corresponding display panel should be turned “on” and which pixels should be turned “off.”

The manufacture of integrated circuit (IC) devices involves a wafer fabrication process in which circuit components (e.g., resistors, diodes, transistors, etc.) and their interconnections are formed on a single wafer of silicon (or other semiconductor substrate). The size and number of circuit components that can be fabricated on a single wafer of silicon is determined by the process node used during the fabrication process. For example, a smaller process node may produce smaller circuit components that are faster and more power-efficient. Because analog devices have greater precision and sensitivity requirements, their circuit components tend to be larger and consume more power than similar circuitry used in digital devices. Thus, the process node used to manufacture the wafer may be optimized for the type of device. For example, larger process nodes may be used to manufacture analog devices whereas smaller process nodes may be used to manufacture digital devices.

### SUMMARY

This Summary is provided to introduce in a simplified form a selection of concepts that are further described below in the Detailed Description. This Summary is not intended to identify key features or essential features of the claims subject matter, nor is it intended to limit the scope of the claimed subject matter.

A method for manufacturing a stacked wafer integrated circuit (IC) device. The method is performed by fabricating first circuitry on a top surface of a first IC wafer and disposing one or more electrical insulators, between the first circuitry, through a depth of the first IC wafer such that the one or more electrical insulators are not exposed on a bottom surface of the first IC wafer. Layers of semiconductor substrate are subsequently removed from a bottom surface of the first IC wafer until the one or more electrical insulators become exposed on the bottom surface of the first IC wafer.

In some embodiments, the first IC wafer is aligned with a second IC wafer, in a stacked configuration, such that the top surface of the first IC wafer faces a top surface of the second IC wafer. The first IC wafer is then bonded with the second IC wafer in the stacked configuration such that the first circuitry disposed on the top surface of the first IC wafer is electrically coupled to second circuitry disposed on the top surface of the second IC wafer. In some aspects, as a result of the bonding, the bottom surface of the first IC wafer forms a top surface of the IC device and the bottom surface of the second IC wafer forms a bottom surface of the IC device.

In some implementations, the first circuitry may be formed on the first IC wafer using a first process node and the second circuitry may be formed on the second IC wafer using a second process node that is different than the first process node. For example, in some aspects, the first process node may be smaller than the second process node. In some implementations, the first circuitry may correspond to digital circuitry and the second circuitry may correspond to analog circuitry. In some aspects, the digital circuitry may be formed on the first IC wafer using a low-power (LP) or embedded-flash (EF) process. In some other aspects, the analog circuitry may be formed on the second IC wafer using a high-voltage (HV) process.

The layers of semiconductor substrate may be removed using backgrinding or chemical mechanical polishing (CMP) techniques. Prior to removing the layers of semiconductor substrate, the bottom surface of at least one of the first IC wafer or the second IC wafer may comprise a semiconductor substrate with no exposed circuitry. In some implementations, the layers of semiconductor substrate may be removed until a combined thickness of the first IC wafer and the second IC wafer, in the stacked configuration, is less than or equal to a threshold thickness. For example, the threshold thickness may correspond to a thickness of the first IC wafer or the second IC wafer prior to removing the layers of semiconductor substrate.

In some other implementations, the step of removing the layers of semiconductor substrate may be performed until one or more circuit components become electrically isolated on the first IC wafer or the second IC wafer as a result. In some other aspects, one or more circuit components may be created on the first IC wafer or the second IC wafer as a result of removing the layers of semiconductor substrate.

### BRIEF DESCRIPTION OF THE DRAWINGS

The present embodiments are illustrated by way of example and are not intended to be limited by the figures of the accompanying drawings.

FIG. 1 shows an example process of manufacturing a mixed-signal integrated circuit (IC) device, in accordance with some embodiments.

FIG. 2 shows a cross-sectional view of a semiconductor wafer in which neighboring circuits are separated using junction isolation techniques.

FIG. 3 shows a cross-sectional view of a semiconductor wafer in which neighboring circuits using an electrical insulator, in accordance with some embodiments.

FIGS. 4A-4F show cross-sectional views of a semiconductor wafer at various stages of a manufacturing process, in accordance with some embodiments.

FIG. 5 shows a cross-sectional view of an example mixed-signal IC device, in accordance with some embodiments.

FIG. 6 shows a semiconductor wafer depicting additional circuit components that can be formed using the embodiments described herein.

FIG. 7 shows another semiconductor wafer 700 depicting additional circuit components that can be formed using the embodiments described herein.

FIG. 8 is an illustrative flowchart depicting an example operation of manufacturing an IC device, in accordance with some embodiments.

### DETAILED DESCRIPTION

In the following description, numerous specific details are set forth such as examples of specific components, circuits, and processes to provide a thorough understanding of the present disclosure. The term “coupled” as used herein means connected directly to or connected through one or more intervening components or circuits. The terms “electronic system” and “electronic device” may be used interchangeably to refer to any system capable of electronically processing information. Also, in the following description and for purposes of explanation, specific nomenclature is set forth to provide a thorough understanding of the aspects of the disclosure. However, it will be apparent to one skilled in the art that these specific details may not be required to practice the example embodiments. In other instances, well-known circuits and devices are shown in block diagram form to avoid obscuring the present disclosure. Some portions of the detailed descriptions which follow are presented in terms of procedures, logic blocks, processing and other symbolic representations of operations on data bits within a computer memory.

These descriptions and representations are the means used by those skilled in the data processing arts to most effectively convey the substance of their work to others skilled in the art. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system. It should be borne in mind, however, that all of these and similar terms are to be associated with the appropriate physical quantities and are merely convenient labels applied to these quantities.

Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention. Also, the example input devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, performs one or more of the methods described above. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor.

The various illustrative logical blocks, modules, circuits and instructions described in connection with the embodiments disclosed herein may be executed by one or more processors. The term “processor,” as used herein may refer to any general purpose processor, conventional processor, controller, microcontroller, and/or state machine capable of executing scripts or instructions of one or more software programs stored in memory. The term “voltage source,” as used herein may refer to a direct-current (DC) voltage source, an alternating-current (AC) voltage source, or any other means of creating an electrical potential (such as ground).

As described above, each of the circuit components on a silicon wafer is fabricated using the same process node. However, some IC devices involve a mix of both analog and digital circuitry (e.g., “mixed-signal” devices). For example, an integrated controller that performs the functions of a touch sensor and a display driver may require analog circuitry for sensing and digital circuitry for display. Fabricating analog circuitry using a process node that is optimized for digital circuitry may incur significantly higher manufacturing costs. On the other hand, fabricating digital circuitry using a process node that is optimized for analog circuitry may result in larger and less-efficient digital circuit components. It is therefore desirable to develop a mixed-signal device that can be manufactured with circuitry optimized for digital and analog applications without incurring unnecessarily high manufacturing costs.

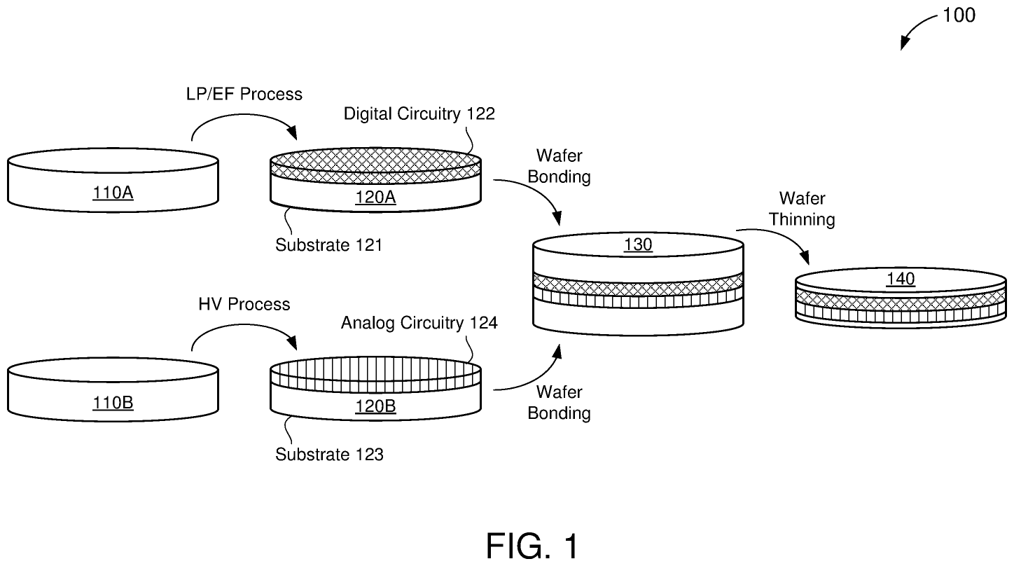

FIG. 1 shows an example process 100 of manufacturing a mixed-signal integrated circuit (IC) 140, in accordance with some embodiments. The process begins with two separate semiconductor wafers 110A and 110B. For example, the wafers 110A and 110B may be formed from silicon or any other suitable semiconductor material (e.g., gallium arsenide). In the example of FIG. 1, the mixed-signal IC 140 is formed from two semiconductor wafers. However, in actual implementations, a mixed-signal IC device may be formed using any number of semiconductor wafers.

Digital circuitry 122 is added to the top surface of the first wafer 110A to produce a resulting “digital” wafer 120A. In some aspects, the digital wafer 120A may include the digital logic and high-speed serializer/de-serializer interface of an integrated display driver. For example, the digital circuitry 122 may include resistors, transistors, diodes, and/or other circuit components that may be used in digital applications. In some embodiments, all of the digital circuitry for the mixed-signal IC 140 may be provided on the digital wafer 120A. Thus, in some aspects, the digital wafer 120A may be fabricated using a process node that is optimized for manufacturing digital components. For example, the digital circuitry 122 may have relatively low power requirements (e.g., 1V transistors). Thus, in some embodiments, a small (e.g., 28, 40, or 55 nm) low-power (LP) or embedded-flash (EF) process may be used to produce the digital circuitry 122 on the digital wafer 120A. As shown in FIG. 1, the top surface of the digital wafer 120A includes the digital circuitry 122 whereas the bottom surface of the digital wafer 120A may comprise a semiconductor substrate 121 with no exposed circuitry.

Analog circuitry 124 is added to the top surface of the second wafer 110B to produce a resulting “analog” wafer 120B. In some aspects, the analog wafer 120B may include the power supply, source drivers, and gate drivers of the integrated display driver. For example, the analog circuitry 124 may include various circuit components used in analog applications. In some embodiments, all of the analog circuitry for the mixed-signal IC 140 may be provided on the analog wafer 120B. Thus, in some aspects, the analog wafer 120B may be fabricated using a process node that is optimized for manufacturing analog components. For example, the analog circuitry 124 may have relatively high power requirements (e.g., 6V or 32V transistors). Thus, in some embodiments, a larger (e.g., 0.8 μm) high-voltage (HV) process may be used to produce the analog circuitry 124 on the analog wafer 120B. As shown in FIG. 1, the top surface of the analog wafer 120B includes the analog circuitry 124 whereas the bottom surface of the digital wafer 120B may comprise a semiconductor substrate 123 with no exposed circuitry.

The digital wafer 120A is then bonded to the analog wafer 120B to produce a stacked wafer 130. For example, the wafers 120A and 120B may be vertically aligned (e.g., in a stacked configuration) with the top surface of the digital wafer 120A facing the top surface of the analog wafer 120B (e.g., with the digital circuitry 122 facing the analog circuitry 124). The wafers 120A and 120B are then bonded face-to-face using known wafer bonding techniques. During the bonding process, the digital circuitry 122 may be coupled to the analog circuitry 124 using bonding pads, routing traces, through-silicon vias (TSVs), and/or various other interconnects.

It is noted that bonding the wafers 120A and 120B face-to-face seals the digital and analog circuitry 122 and 124 inside the stacked wafer 130. For example, as shown in FIG. 1, the bottom surface (e.g., substrate 121) of the digital wafer 120A may form the top surface of the stacked wafer 130 and the bottom surface (e.g., substrate 123) of the analog wafer 120B may form the bottom surface of the stacked wafer 130. Thus, the digital and analog circuitry 122 and 124 is fully contained between the layers of substrate 121 and 123. Since the circuitry within the stacked wafer 130 is not exposed (e.g., cannot be seen) on the top surface or the bottom surface of the stacked wafer 130, the stacked wafer 130 embodiment of FIG. 1 may provide greater protection to the digital and analog circuitry 122 and 124 contained therein.

Finally, the stacked wafer 130 may be thinned down to produce the mixed-signal IC 140. For example, the stacked wafer 130 may be thinned down to a desired thickness, such as the thickness of a single semiconductor wafer (e.g., wafer 110A or 110B). During the wafer thinning process, material or substrate from the exposed sides of the stacked wafer 130 may be removed using known backgrinding or chemical mechanical polishing (CMP) techniques. In some embodiments, the wafer thinning process may be used to produce (or complete the fabrication of) one or more circuit components of the mixed-signal IC 140. As described in greater detail below, the wafer thinning process may separate the substrate 121 (e.g., on which the digital circuitry 122) and/or substrate 123 (e.g., on which the analog circuitry 124 is formed) into discrete portions, thereby isolating individual circuit components from one another.

In the example of FIG. 1, wafer thinning is performed after wafer bonding. However, in actual implementations, the analog wafer 120B and/or the digital wafer 120A may be thinned prior to bonding. In some embodiments, the analog side of the stacked wafer 130 (e.g., corresponding to analog wafer 120B) may be thinned first, to complete the fabrication of one or more analog circuit components, and the digital side of the stacked wafer 130 (e.g., corresponding to digital wafer 120A) may then be thinned down to the desired overall thickness of the mixed-signal IC 140. In other embodiments, the digital side of the stacked wafer 130 may be thinned first, to complete the fabrication of one or more digital circuit components, and the analog side of the stacked wafer 130 may then be thinned down to the desired overall thickness of the mixed-signal IC 140.

The mixed-signal IC 140 offers several advantages over conventional (e.g., monolithic) mixed-signal devices. As described above, the process node used to manufacture a monolithic wafer may be deterministic of the size and/or number of circuit components on the wafer. As a result of fabricating both analog and digital circuitry using the same process node, the analog circuitry may be fabricated using a process node that is smaller than necessary (e.g., incurring high manufacturing costs) or the digital circuitry may be fabricated using a process node that is larger than necessary (e.g., producing larger and less-efficient circuitry). Aspects of the present disclosure recognize that, by manufacturing the mixed-signal IC 140 on multiple semiconductor wafers (e.g., wafers 110A and 110B), the digital circuitry 122 and analog circuitry 124 may be fabricated using different process nodes. More specifically, the digital circuitry 122 may be fabricated using a process that is optimized for digital circuit components (e.g., 28/40/55 LP/EF) and the analog circuitry 124 may be fabricated using a process that is optimized for analog circuit components (e.g., 80 HV). This may significantly reduce manufacturing costs while ensuring optimal performance of the mixed-signal IC 140.

Among other advantages, the mixed-signal IC 140 also protects the circuitry therein by encapsulating the digital circuitry 122 and analog circuitry 124 on the inside (e.g., unexposed portion) of the IC 140. Further, the wafer thinning process may electrically isolate circuit components of the mixed-signal IC 140 by removing at least a portion of the substrate interconnecting the components. This may allow for a denser packing of analog circuitry 124 and/or digital circuitry 122 on the mixed-signal IC 140, which may allow a greater number chips or die to be cut from the mixed-signal IC 140. As a result, the process 100 may further reduce the manufacturing costs of individual mixed-signal IC chips.

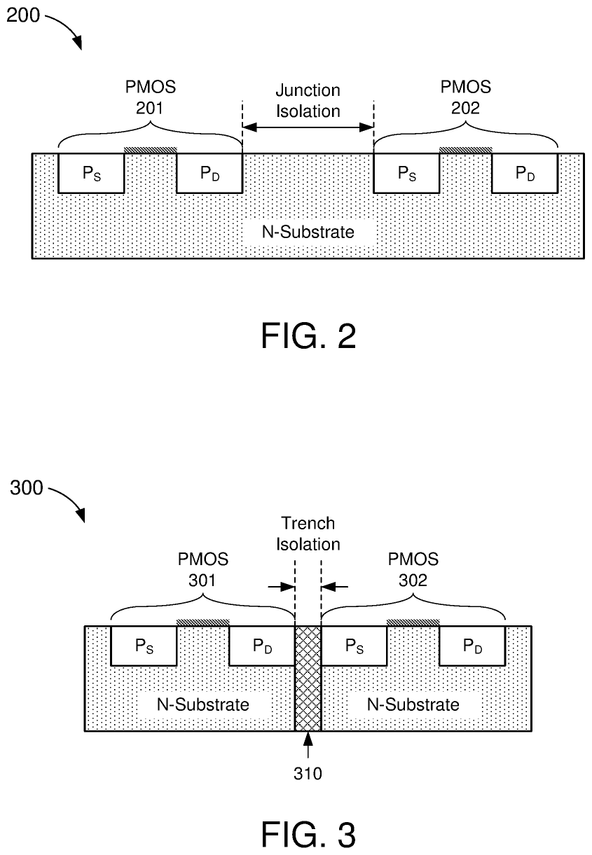

FIG. 2 shows a cross-sectional view of a semiconductor wafer 200 in which neighboring circuits are separated using junction isolation techniques. The semiconductor wafer 200 may be an example embodiment of the digital wafer 120A or the analog wafer 120B of FIG. 1. Thus, in some embodiments, the semiconductor wafer 200 may include the digital circuit components of a mixed-signal IC (e.g., corresponding to digital circuitry 122). In other embodiments, the semiconductor wafer 200 may include the analog circuit components of a mixed-signal IC (e.g., corresponding to analog circuitry 124).

The semiconductor wafer 200 is formed from an N-type (negatively-doped) semiconductor substrate. Two P-type (positively-doped) semiconductor regions are deposited on either side of the substrate to form respective P-type metal oxide semiconductors (PMOS) transistors 201 and 202. In some embodiments, each of the P-type regions may be a heavily-doped P-type semiconductor (P+) region. More specifically, each P-type region may form a source or drain of the corresponding PMOS transistor 201 or 202. In the example of FIG. 2, the left-most P-type region of each PMOS transistor 201 and 202 is the source terminal (P_{S}) for that transistor, and the right-most P-type region of each PMOS transistor 201 and 202 is the drain terminal (P_{D}) for that transistor. The N-type substrate forms a channel between the P-type regions of each PMOS transistor 201 and 202, and a layer of oxide is provided on the surface of the channel to form the gate of the transistor.

Each P-N junction (e.g., the intersection between a P-type region and the N-type substrate) acts as a diode and thus facilitates a flow of charge from one region to another when a voltage is applied between the P-type region and the N-type substrate. Accordingly, the N-type substrate facilitates a flow of charge between the source and drain (e.g., P-type regions) of each PMOS transistor 201 and 202 when the corresponding transistor is properly biased. However, if the PMOS transistors 201 and 202 are too close to one another, the N-type substrate may also facilitate a flow of charge from the source of one PMOS transistor to the drain of a neighboring PMOS transistor (e.g., from P_{S} of PMOS 201 to P_{D} of PMOS 202) when biased a certain way.

To prevent such undesired coupling between the PMOS transistors 201 and 202, the transistors may be separated by at least a threshold distance (referred to herein as a “junction isolation distance”). For example, the junction isolation distance may be the minimum distance of separation needed to prevent the P-N junction of one PMOS transistor from overlapping or otherwise forming a channel with the P-N junction of a neighboring PMOS transistor. In the example of FIG. 2, the junction isolation distance may be the minimum distance needed to separate the drain P_{D} of the first PMOS transistor 201 from the source P_{S} of the second PMOS transistor 202 in order to ensure that the transistors 201 and 202 are electrically isolated from one another.

It is noted that, although two PMOS transistors 201 and 202 are depicted in the example of FIG. 2, the junction isolation distance may apply to any integrated circuit components (e.g., PMOS transistors, NMOS transistors, diodes, etc.) that are disposed on the same substrate. As a result, the number of circuit components that can be formed on a semiconductor wafer or die may be limited by the junction isolation distance needed to separate each of the circuit components. This problem may be more pronounced in analog circuitry (e.g., than digital circuitry), as larger circuit components may require larger junction isolation distances than smaller circuit components.

Aspects of the present disclosure recognize that an electrical insulator (such as an oxide material) may better isolate neighboring circuit components (such as PMOS transistors 201 and 202) than a semiconductor (such as the N-type substrate). Furthermore, the thickness of an insulator may be substantially less than the thickness of a semiconductor needed to provide the same degree of electrical isolation. Thus, in some embodiments, the circuit components of a mixed-signal device may be electrically isolated using an insulator material (e.g., silicon dioxide or other oxide material) in lieu of junction isolation techniques.

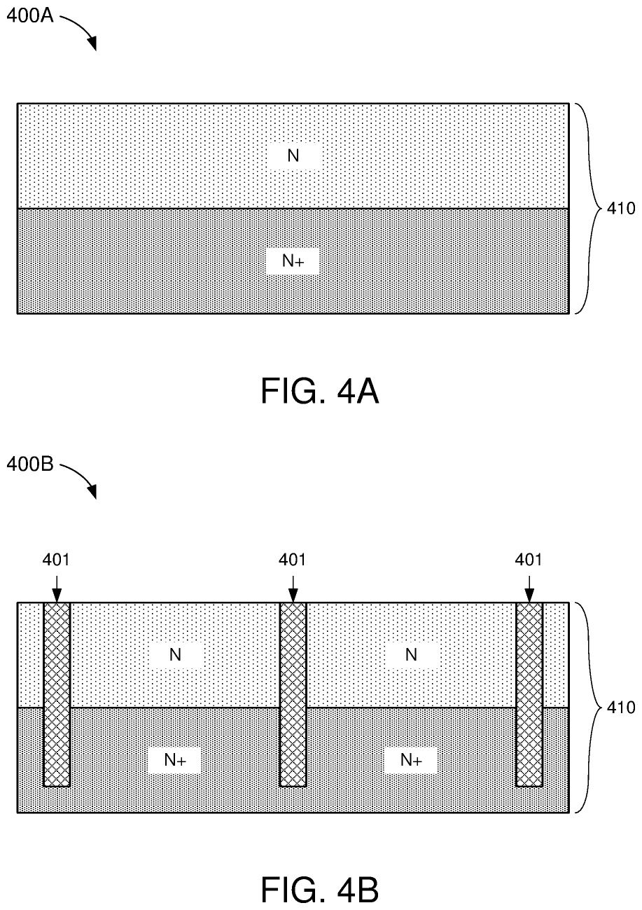

FIG. 3 shows a cross-sectional view of a semiconductor wafer 300 in which neighboring circuits are separated using an electrical insulator, in accordance with some embodiments. The semiconductor wafer 300 may be an example embodiment of the digital wafer 120A or the analog wafer 120B of FIG. 1. Thus, in some embodiments, the semiconductor wafer 300 may include the digital circuit components of a mixed-signal IC (e.g., corresponding to digital circuitry 122). In other embodiments, the semiconductor wafer 300 may include the analog circuit components of a mixed-signal IC (e.g., corresponding to analog circuitry 124).

The semiconductor wafer 300 is formed from an N-type (negatively-doped) semiconductor substrate. Two P-type (positively-doped) semiconductor regions are deposited on either side of the substrate to form respective PMOS transistors 301 and 302. In some embodiments, each of the P-type regions may be a heavily-doped P-type semiconductor (P+) region. More specifically, each P-type region may form a source or drain of the corresponding PMOS transistor 301 or 302. In the example of FIG. 3, the left-most P-type region of each PMOS transistor 301 and 302 is the source terminal (P_{S}) for that transistor, and the right-most P-type region of each PMOS transistor 301 and 302 is the drain terminal (P_{D}) for that transistor. The N-type substrate forms a channel between the P-type regions of each PMOS transistor 301 and 302, and a layer of oxide is provided on the surface of the channel to form the gate of the transistor.

In some embodiments, an electrical insulator 310 (e.g., an oxide material) is deposited between the PMOS transistors 301 and 302. More specifically, the electrical insulator 310 may be provided between the drain P_{D} of the first PMOS transistor 301 and the source P_{S} of the second PMOS transistor 302. The insulator 310 may form an electrical barrier between the neighboring PMOS transistors 301 and 302, preventing the flow of charge from one of the transistors to the other (e.g., from P_{S} of PMOS 301 to P_{D} of PMOS 302). In some embodiments, the insulator 310 may be trenched through the entire thickness of the substrate to fully isolate or wall-off the first PMOS transistor 301 from the second PMOS transistor 302. For example, the electrical insulator 310 may be exposed on either side of the wafer 300, causing the N-type substrate to be bifurcated into separate and distinct regions coinciding with respective PMOS transistors 301 and 302. As a result of this “trench isolation,” the N-type substrate cannot form a channel between the PMOS transistors 301 and 302.

It is noted that the electrical insulator 310 may effectively isolate the first PMOS transistor 301 from the second PMOS transistor 302 with a significantly smaller degree of separation between the transistors compared to junction isolation techniques (e.g., as shown in FIG. 2). This may allow for a greater number and/or density of circuit components to be formed on the semiconductor wafer 300 than would otherwise be possible using junction isolation techniques. For example, using the trench isolation techniques described herein, the spacing between 6V transistors (e.g., analog circuitry) may be reduced from 10 μm (e.g., the junction isolation distance) to 0.5 μm. Although two PMOS transistors 301 and 302 are depicted in the example of FIG. 3, the trench isolation techniques may be applied to any integrated circuit components (e.g., PMOS transistors, NMOS transistors, diodes, etc.) that are disposed on the same substrate.

As described above, in order to achieve the maximum benefits of trench isolation, the electrical insulator 310 should be trenched through the entire thickness of the substrate. However, it may not be feasible or cost-effective to deposit the electrical insulator 310 through the depth of a conventional semiconductor wafer (such as wafer 110A or 110B of FIG. 1). For example, the electrical insulator 310 may be formed by etching a trench into the semiconductor wafer and filling the trench with an oxide material (such as silicon dioxide). However, etching a trench through the entire thickness of a semiconductor wafer may compromise the structural integrity of the wafer (e.g., causing portions of the wafer to separate or break off). Furthermore, it may be difficult to fill the trench with oxide material once it has completely etched through the top and bottom surfaces of the wafer. Thus, in some embodiments, the electrical insulator 310 may be formed by etching a trench through the top surface the semiconductor wafer (e.g., without penetrating the bottom surface of the wafer), filling the trench with an oxide material, and removing layers of substrate from the bottom surface until the oxide trenches are exposed on the bottom surface of the semiconductor wafer. In some aspects, the layers of substrate may be removed using a backgrinding technique.

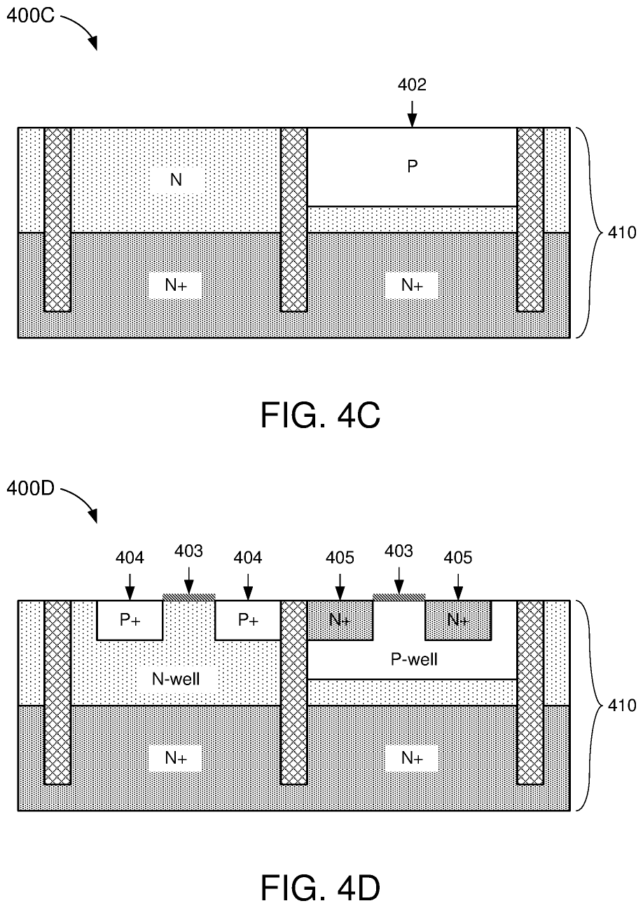

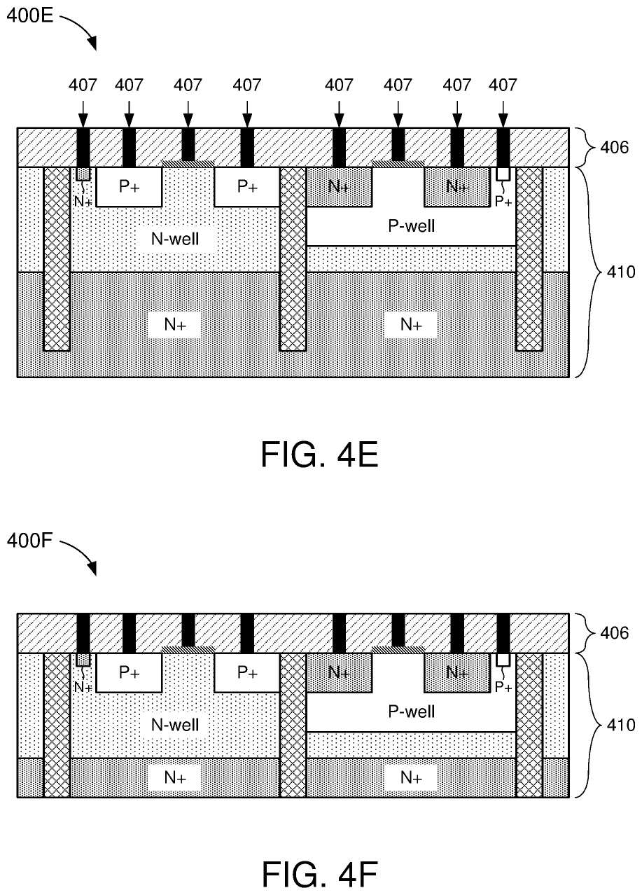

FIGS. 4A-4F show cross-sectional views 400A-400F of a semiconductor wafer 410 at various stages of a manufacturing process, in accordance with some embodiments. The semiconductor wafer 410 may be an example embodiment of the digital wafer 120A or the analog wafer 120B of FIG. 1. Thus, in some embodiments, the semiconductor wafer 410 may include the digital circuit components (e.g., corresponding to digital circuitry 122). In other embodiment embodiments, the semiconductor wafer 410 may include the analog circuit components (e.g., corresponding to analog circuitry 124).

As shown in FIG. 4A, the semiconductor wafer 410 may comprise a lightly-doped N-type semiconductor region (N) formed on top of a heavily-doped N-type semiconductor substrate (N+). For example, the wafer 410 may be formed from a semiconductor material such as silicon. The N and N+ semiconductor regions may be formed using dopant gases, ion implantation, or any other suitable doping techniques. Although the semiconductor wafer 410 is shown to include an N-type semiconductor region formed on top of an N+ substrate, other doping configurations may be implemented with little or no modification to the process of FIGS. 4A-4F. For example, in some embodiments, the semiconductor wafer 410 may comprise a lightly-doped P-type semiconductor region (P) formed on top of a heavily-doped P-type semiconductor substrate (P+).

As shown in FIG. 4B, electrical insulators 401 are deposited in the semiconductor wafer 410. In some embodiments, the electrical insulators 401 may be formed by etching respective trenches into the semiconductor wafer 410 (e.g., at the locations of the insulators 401) and filling the trenches with an oxide material (such as silicon dioxide). In some aspects, the trenches may be etched to a depth below the N-type semiconductor region and into at least a portion of the N+ semiconductor substrate. However, the trenches may not be etched through the entire thickness of the semiconductor wafer 410 (e.g., trenches may not penetrate the bottom surface of the wafer 410). As described above, the electrical insulators 401 may be used to electrically isolate various circuit components of the semiconductor wafer 410. Thus, the number and configuration of electrical insulators 401 may depend on the number and configuration of the circuit components to be formed on the semiconductor wafer 410.

As shown in FIG. 4C, a P-type semiconductor region is implanted in the right-hand portion of the wafer 410. The P-type semiconductor region may be formed using dopant gases, ion implantation, or any other suitable doping techniques. In the example of FIG. 4C, the P-type semiconductor region may be deposited between a set of electrical insulators 401. Thus, at least one of the electrical insulators 401 may separate the N-type semiconductor region (on the left) from the P-type semiconductor region (on the right). More specifically, the electrical insulators 401 may prevent a P-N junction from being formed at an intersection of the N-type semiconductor region and the P-type semiconductor region. In some embodiments, the N-type semiconductor region may form an N-well (e.g., for PMOS transistors) and the P-type semiconductor region may form a P-well (e.g., for NMOS transistors).

As shown in FIG. 4D, a PMOS transistor is formed in the left-hand portion of the wafer 410 and an NMOS transistor is formed on the right-hand portion of the wafer 410. For example, the PMOS transistor may be formed by implanting two heavily-doped P-type (P+) semiconductor regions 404 in the N-well to form respective source and drain terminals, where the N-well forms a channel between the source and drain of the PMOS transistor. The NMOS transistor may be formed by implanting two heavily-doped N-type (N+) semiconductor regions 405 in the P-well to form respective source and drain terminals, wherein the P-well forms a channel between the source and drain of the NMOS transistor. A layer of oxide 403 (such as silicon dioxide) is grown on the surface of the wafer 410 to form respective gate terminals for the PMOS transistor and NMOS transistor. For example, after growing the layer of oxide 403 on the surface of the wafer 410, portions of the oxide 403 may be etched away leaving behind the gates above respective channels between the P-type regions 404 and N-type regions 405. In some embodiments, a layer of polysilicon (not shown for simplicity) may be formed above each of the gates to form respective gate contacts.

As shown in FIG. 4E, an intermediate layer of oxide 406 may be formed on the surface of the wafer 410. The intermediate oxide layer 406 may be used to seal off the top surface of the semiconductor wafer 410, for example, to protect the circuit components disposed thereon from shorting and/or forming undesired connections with other circuitry. A plurality of contacts 407 are formed in the intermediate oxide layer 406 to form electrical connections between the circuit components (e.g., PMOS transistor and NMOS transistor) of the wafer with external circuitry. For example, each of the contacts 407 may be formed by etching respective portions of the oxide layer 406 and depositing metal within the etched portions of the oxide layer 406 (or by any other means commonly known in the industry for creating contacts to silicon). In the example of FIG. 4E, a respective contact 407 is coupled to each of the N-well, the P-well, the P-type regions, the N-type regions, and the oxide gates. In some embodiments, heavily-doped N-type (N+) and P-type (P+) regions may be implanted in the N-well and P-well, respectively, to form ohmic contacts with one or more of the contacts 407. In some embodiments, the intermediate oxide layer 406 may additionally function as in interface between the semiconductor wafer 410 and another semiconductor wafer (not shown for simplicity) to be stacked and bonded on top of the wafer 410.

As shown in FIG. 4F, one or more layers of semiconductor material (e.g., corresponding to the N+ substrate) may be removed from the bottom surface of the wafer 410. For example, the layers of semiconductor material may be removed by backgrinding the bottom surface of the wafer 410 to a desired depth or thickness. It is noted that, prior to removing any layers of semiconductor material, the bottom surface of the wafer 410 may comprise a semiconductor substrate that is uniform throughout (e.g., with no exposed circuitry). In some embodiments, the bottom surface of the wafer 410 is grinded to at least the depth of the electrical insulators 401 (e.g., such that the electrical insulators 401 are exposed on the bottom surface of the wafer 410).

Aspects of the present disclosure recognize that the oxide material of the electrical insulators 401 may be harder to grind than the semiconductor substrate. Thus, in some aspects, the depth of the electrical insulators 401 may be used to control a depth of the backgrinding. For example, the backgrinding process may stop once the electrical insulators 401 become exposed on the bottom surface of the wafer 410. As a result of the backgrinding process, the N+ substrate may be bifurcated between the region containing the PMOS transistor and the region containing the NMOS transistor. Accordingly, the N+ substrate cannot form a channel between the PMOS transistor (on the left of the wafer 410) and the NMOS transistor (on the right of the wafer 410).

It is noted that, although a single PMOS transistor and NMOS transistor is depicted in the example of FIGS. 4A-4F, the process described above may be used to fabricate various any number of NMOS and/or PMOS transistors, including various other integrated circuit components (e.g., as described in greater detail below). Moreover, the process of FIGS. 4A-4F allows the circuit components of a semiconductor wafer to be electrically isolated using trench isolation techniques (e.g., as described with respect to FIG. 3). Thus, a greater number and/or density of circuit components may be formed on a single semiconductor wafer using the process of FIGS. 4A-4F in comparison to using conventional IC fabrication techniques (e.g., which rely on junction isolation).

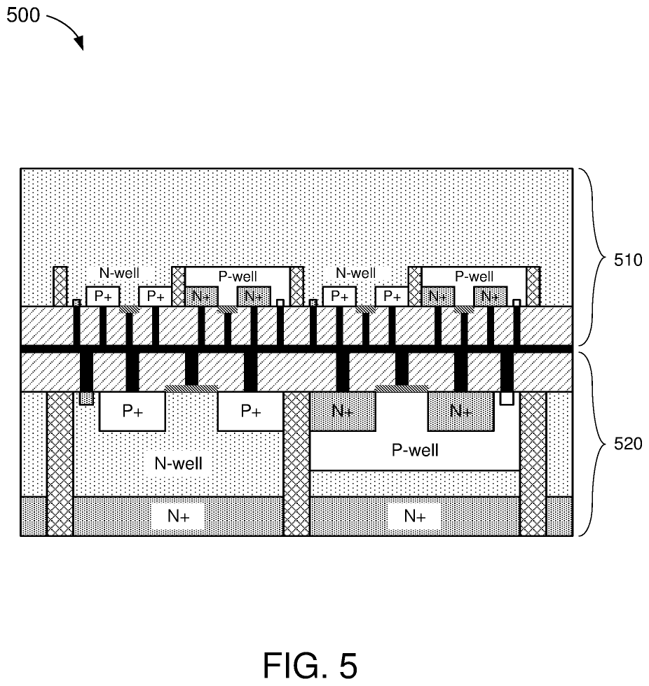

FIG. 5 shows a cross-sectional view of an example mixed-signal IC device 500, in accordance with some embodiments. The mixed-signal IC device 500 includes a first wafer 510 stacked on top of, and bonded to, a second wafer 520. The mixed-signal IC device 500 may be an example embodiment of the mixed-signal IC 140 of FIG. 1. Thus, the first wafer 510 may be an example embodiment of the digital wafer 120A and the second wafer 520 may be an example embodiment of the analog wafer 120B.

The first wafer 510 (referred to hereinafter as the “digital wafer”) may include any digital circuitry for the mixed-signal IC device 500. In some embodiments, the first wafer 510 may be fabricated using a process node that is optimized for manufacturing digital circuit components (such as a 28, 40, or 55 nm LP or EF process). In the example of FIG. 5, the digital wafer 510 is shown to include a number of PMOS transistors (e.g., formed by a pair of P-type regions deposited in each N-well) and a number of NMOS transistors (e.g., formed by a pair of N-type regions deposited in each P-well). However, in actual implementations, the digital wafer 510 may include various other circuit components (not shown for simplicity) in addition to, or in lieu of, the circuit components shown in FIG. 5.

The second wafer 520 (referred to hereinafter as the “analog wafer”) may include any analog circuitry for the mixed-signal IC device 500. In some embodiments, the second wafer 520 may be fabricated using a process node that is optimized for manufacturing analog circuit components (such as an 80 μm HV process). In the example of FIG. 5, the analog wafer 520 is shown to include a PMOS transistor (e.g., formed by a pair of P-type regions deposited in the N-well) and an NMOS transistor (e.g., formed by a pair of N-type regions deposited in the P-well). However, in actual implementations, the analog wafer 520 may include various other circuit components (not shown for simplicity) in addition to, or in lieu of, the circuit components shown in FIG. 5. In some aspects, the analog wafer 520 may be an example embodiment of the semiconductor wafer 410 of FIGS. 4A-4F. Thus, the circuit components disposed on the analog wafer 520 may be electrically isolated using trench isolation techniques (e.g., as described above with respect to FIG. 3).

As shown in FIG. 5, the wafers 510 and 520 are stacked and bonded face-to-face. For example, the wafers 510 and 520 may be bonded using known wafer bonding techniques. During the bonding process, one or more circuit components (e.g., transistors) of the digital wafer 510 may be coupled to one or more circuit components (e.g., transistors) of the analog wafer 520. For example, the junction or interface between the digital wafer 510 and analog wafer 520 may include one or more bonding pads, routing traces, TSVs, and/or various other interconnects for coupling the circuitry of the digital wafer 510 to the circuitry of the analog wafer 520. In the example of FIG. 5, the wafers 510 and 520 are bonded such that the circuit components of each wafer is fully contained on the inside of the mixed-signal IC device 500. For example, as shown in FIG. 5, neither the transistors of the digital wafer 510 nor the transistors of the analog wafer 520 are exposed on either the top surface or the bottom surface of the mixed-signal IC device 500.

In some embodiments, the analog wafer 520 is thinned to a desired depth or thickness (e.g., by removing one or more layers of substrate from the bottom surface of the analog wafer 520). In some aspects, the bottom surface of the analog wafer 520 is backgrinded to at least the depth of the electrical insulators (e.g., forming the trench isolation between circuit components) deposited in the wafer 520. In other embodiments, the digital wafer 510 may also be thinned to a desired depth or thickness (e.g., by removing one or more layers of substrate). For example, the digital wafer 510 may be backgrinded to achieve a desired overall thickness for the mixed-signal IC device 500. In some aspects, the desired overall thickness of the mixed-signal IC device 500 may be substantially similar to the thickness of a single semiconductor wafer.

The mixed-signal IC device 500 offers several advantages over conventional (e.g., monolithic) mixed-signal devices. For example, by forming the mixed-signal IC device 500 from multiple semiconductor wafers 510 and 520, each of the wafers 510 and 520 may be fabricated using a different process node. More specifically, the circuit components of the digital wafer 510 may be fabricated using a process that is optimized for digital circuit components (e.g., 28/40/55 LP/EF) whereas the circuit components of the analog wafer 520 may be fabricated using a process that is optimized for analog circuit components (e.g., 80 HV). This may significantly reduce manufacturing costs will ensuring optimal performance of the mixed-signal IC device 500.

Among other advantages, the mixed-signal IC device 500 also protects the circuitry therein by encapsulating the circuit components of the digital wafer 510 and the circuit components of the analog wafer 520 on the inside (e.g., unexposed) portion of the IC device 500. Further, the thinning of the analog wafer 520 (and/or the digital wafer 510) may electrically isolate circuit components provided thereon via trench isolation. This may allow for a greater number or density of circuit components to be packed onto the analog wafer 520 (and/or digital wafer 510).

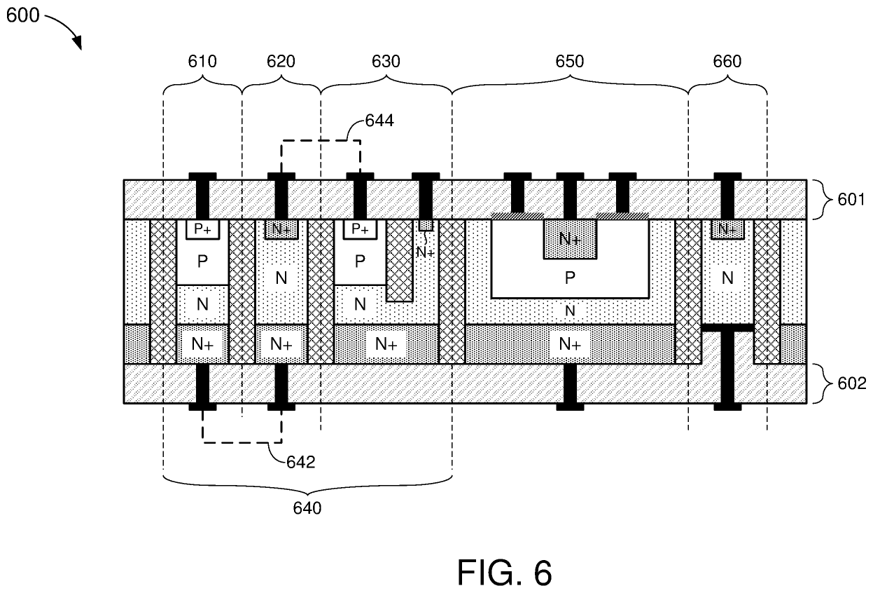

FIG. 6 shows a semiconductor wafer 600 depicting additional circuit components that can be formed using the embodiments described herein. The semiconductor wafer 600 may be an example embodiment of the digital wafer 120A or the analog wafer 120B of FIG. 1. Thus, in some embodiments, the semiconductor wafer 600 may include the digital circuit components of a mixed-signal IC (e.g., corresponding to digital circuitry 122). In other embodiments, the semiconductor wafer 600 may include the analog circuit components of a mixed-signal IC (e.g., corresponding to analog circuitry 124). It is noted that the example circuit components shown in FIG. 6 are described for illustrative purposes only. In actual implementations, the semiconductor wafer 600 may include fewer or more circuit components than those depicted in FIG. 6 (including other circuit components not shown in the example of FIG. 6).

In the example of FIG. 6, the semiconductor wafer 600 is shown to include a vertical diode 610, a via 620, a horizontal diode 630, an electrostatic discharge (ESD) diode 640, a vertical lateral double-diffused metal oxide semiconductor (LDMOS) 650, and a Schottky diode 660. With reference for example to FIGS. 4A-4B, a trench isolation process may be used to fabricate each of the circuit components 610-660 on the semiconductor wafer 600. More specifically, each of the circuit components 610-660 may be electrically isolated by one or more electrical insulators (such as the electrical insulators 401 of FIG. 4B). The semiconductor wafer 600 may initially comprise a lightly-doped N-type semiconductor region (N) formed on top of a heavily-doped N-type semiconductor (N+) substrate (such as the semiconductor wafer 410 shown in FIG. 4A). Intermediate oxide layers 601 and 602 (such as oxide layer 406 of FIG. 4E) may be formed on both the top surface and bottom surface of the semiconductor wafer 600 (e.g., after wafer-thinning) to protect the circuitry therein.

The vertical diode 610 may be formed by implanting a P-type semiconductor region in at least a portion of the lightly-doped N-type region of the semiconductor wafer 600. A diode is thus formed at the vertical P-N junction between the P-type region and the N-type region and/or the N+ substrate. An electrical contact (such as contacts 407 of FIG. E) may be deposited in the first intermediate oxide layer 601 to provide a point of contact for a first terminal (e.g., the P-type region) of the diode 610. In some embodiments, a heavily-doped P-type (P+) sub-region may be implanted in the P-type semiconductor region to form an ohmic contact with the electrical contact at the first terminal of the diode 610. Another electrical contact may be deposited in the second intermediate oxide layer 602 to provide a point of contact for a second terminal (e.g., the N-type region) of the diode 610.

The via 620 may be formed by isolating a section of the semiconductor wafer 600 between two or more electrical insulators. For example, the isolated section of the semiconductor wafer 600 (e.g., including a portion of the N-type region and N+substrate) may form a conductive path from the top surface of the wafer 600 to the bottom surface of the wafer 600. Thus, the via 620 may perform and/or function as a TSV. An electrical contact may be deposited in the first intermediate oxide layer 601 to provide a point of contact for a first terminal of the via 620. In some embodiments, a heavily-doped N-type (N+) sub-region may be implanted in the N-type region to form an ohmic contact with the electrical contact at the first terminal of the via 620. Another electrical contact may be deposited in the second intermediate oxide layer 602 to provide a point of contact for a second terminal of the via 620.

The horizontal diode 630 may be formed by implanting a P-type semiconductor region in at least a portion of the lightly-doped N-type region of the semiconductor wafer 600 and using a shallow oxide trench to isolate the P-type region from the remainder of the N-type region. In the example of FIG. 6, the shallow oxide trench is formed to the right of the P-type region and extends deeper into the N-type region than the depth of the P-type region. A diode is thus formed at the vertical P-N junction between the P-type region and the N-type region and/or the N+ substrate. A first electrical contact may be deposited in the first intermediate oxide layer 601 to provide a point of contact for a first terminal (e.g., the P-type region) of the diode 630. In some embodiments, a heavily-doped P-type (P+) sub-region may be implanted in the P-type region to form an ohmic contact with the electrical contact at the first terminal of the diode 630. A second electrical contact may be deposited in the second intermediate oxide 602 to provide a point of contact for a second terminal (e.g., the N-type region) of the diode 630. In some embodiments, a heavily-doped N-type (N+) sub-region may be implanted in the N-type region to form an ohmic contact with the electrical contact at the second terminal of the diode 630.

The ESD diode 640 may be formed by coupling any pair of diodes, formed on the semiconductor wafer 600, in series. In the example of FIG. 6, the ESD diode 640 is formed by coupling the vertical diode 610 in series with the horizontal diode 630. For example, the vertical diode 610 may be coupled to the horizontal diode 630 by coupling the second terminal (e.g., the N-type region) of the vertical diode 610 to the first terminal (e.g., the P-type region) of the horizontal diode 630. It is noted that the second terminal of the vertical diode 610 and the first terminal of the horizontal diode 630 are on opposite surfaces of the semiconductor wafer 600. Thus, in some embodiments, a via (such as via 620) may be used to facilitate the coupling between the diodes 610 and 630. As shown in FIG. 6, the second terminal of the vertical diode 610 may be coupled (e.g., via a conductive trace, wire, or other electrical connection 642) to the second terminal of the via 620, and the first terminal of the via 620 may be coupled (e.g., via a conductive trace, wire, or other electrical connection 644) to the first terminal of the horizontal diode 630. It is noted that, in other implementations, an ESD diode may be formed by coupling two vertical diodes or two horizontal diodes in series with one another.

The vertical LDMOS 650 may be formed by implanting a P-well in the N-type region of the semiconductor wafer 600 and implanting a heavily-doped N-type (N+) region within the P-well. A pair of oxide gates may be grown on top of the P-well, on either sides of the N-type region implanted therein. In the example of FIG. 6, the N-type region surrounding the P-well may function as a drift region for the drain (e.g., N+ substrate) of the vertical LDMOS 650. An electrical contact may be deposited in the first intermediate oxide layer 601 to provide a point of contact for a first terminal (e.g., the N-type region within the P-well) of the LDMOS 650. Additional electrical contacts may be deposited in the first intermediate oxide layer 601 to provide respective points of contact for the gates of the LDMOS 650. Another electrical contact may be deposited in the second intermediate oxide layer 602 to provide a point of contact for a second terminal (e.g., the N+ substrate) of the LDMOS 650.

The Schottky diode 660 may be formed by etching away the N+ substrate between two or more electrical insulators and depositing a layer of metal across the bottom of the N-type region (e.g., where the N+ substrate is removed). A Schottky barrier is thus formed at the vertical junction between the N-type semiconductor and the metal layer. An electrical contact may be deposited in the first intermediate oxide layer 601 to provide a point of contact for a first terminal (e.g., the N-type semiconductor) of the Schottky diode 660. In some embodiments, a heavily-doped N-type (N+) sub-region may be implanted in the N-type region to form an ohmic contact with the electrical contact at the first terminal of the Schottky diode 660. Another electrical contact may be deposited in the second intermediate oxide layer 602 to provide a point of contact for a second terminal (e.g., the metal layer) of the Schottky diode 660.

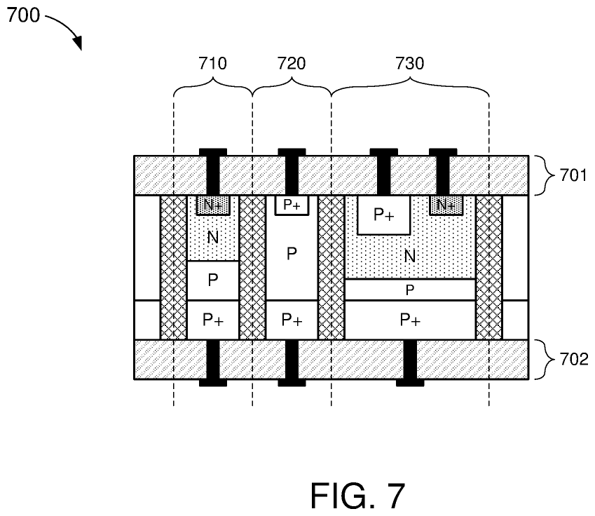

FIG. 7 shows another semiconductor wafer 700 depicting additional circuit components that can be formed using the embodiments described herein. The semiconductor wafer 700 may be an example embodiment of the digital wafer 120A or the analog wafer 120B of FIG. 1. Thus, in some embodiments, the semiconductor wafer 700 may include the digital circuit components of a mixed-signal IC (e.g., corresponding to digital circuitry 122). In other embodiments, the semiconductor wafer 600 may include the analog circuit components of a mixed-signal IC (e.g., corresponding to analog circuitry 124). It is noted that the example circuit components shown in FIG. 7 are described for illustrative purposes only. In actual implementations, the semiconductor wafer 700 may include fewer or more circuit components than those depicted in FIG. 7 (including other circuit components not shown in the example of FIG. 7).

In the example of FIG. 7, the semiconductor wafer 700 is shown to include a vertical diode 710, a via 720, and a bipolar junction (PNP) transistor 730. With reference for example to FIGS. 4A-4B, a trench isolation process may be used to fabricate each of the circuit components 710-730 on the semiconductor wafer 700. More specifically, each of the circuit components 710-730 may be electrically isolated by one or more electrical insulators (such as the electrical insulators 401 of FIG. 4B). The semiconductor wafer 700 may initially comprise a lightly-doped P-type semiconductor region (P) formed on top of a heavily-doped P-type semiconductor (P+) substrate (such as the semiconductor wafer 410 shown in FIG. 4A). Intermediate oxide layers 701 and 702 (such as oxide layer 406 of FIG. 4E) may be formed on both the top surface and bottom surface of the wafer 700 (e.g., after wafer-thinning) to protect the circuitry therein.

The vertical diode 710 may be formed by implanting an N-type semiconductor region in at least a portion of the lightly-doped P-type region of the semiconductor wafer 700. A diode is thus formed at the vertical P-N junction between the N-type region and the P-type region and/or the P+ substrate. An electrical contact (such as contacts 407 of FIG. E) may be deposited in the first intermediate oxide layer 701 to provide a point of contact for a first terminal (e.g., the N-type region) of the diode 710. In some embodiments, a heavily-doped N-type (N+) sub-region may be implanted in the N-type semiconductor region to form an ohmic contact with the electrical contact at the first terminal of the diode 710. Another electrical contact may be deposited in the second intermediate oxide layer 702 to provide a point of contact for a second terminal (e.g., the P-type region) of the diode 710.

The via 720 may be formed by isolating a section of the semiconductor wafer 700 between two or more electrical insulators. For example, the isolated section of the semiconductor wafer 700 (e.g., including a portion of the P-type region and P+ substrate) may form a conductive path from the top surface of the wafer 700 to the bottom surface of the wafer 700. Thus, the via 720 may perform and/or function as a TSV. An electrical contact may be deposited in the first intermediate oxide layer 701 to provide a point of contact for a first terminal of the via 720. In some embodiments, a heavily-doped P-type (P+) sub-region may be implanted in the P-type region to form an ohmic contact with the electrical contact at the first terminal of the via 720. Another electrical contact may be deposited in the second intermediate oxide layer 702 to provide a point of contact for a second terminal of the via 720.

The PNP transistor 730 may be formed by implanting an N-well in the P-type region of the semiconductor wafer 700 and implanting a heavily-doped P-type (P+) region within the N-well. A vertical bipolar junction transistor (BJT) is thus formed between the top surface of the wafer 700 and the bottom surface of the wafer 700. An electrical contact may be deposited in the first intermediate oxide layer 701 to provide a point of contact for a first terminal (e.g., the P+ region) of the PNP transistor 730. Another electrical contact may be deposited in the first intermediate oxide layer 701 to provide a point of contact for the base (e.g., the N-well) of the PNP transistor 730. In some embodiments, a heavily-doped N-type (N+) sub-region may be implanted in the N-well to form an ohmic contact with the electrical contact at the base of the PNP transistor 730. A third electrical contact may be deposited in the second intermediate oxide layer 702 to provide a point of contact for a second terminal (e.g., the P+ substrate) of the PNP transistor 730.

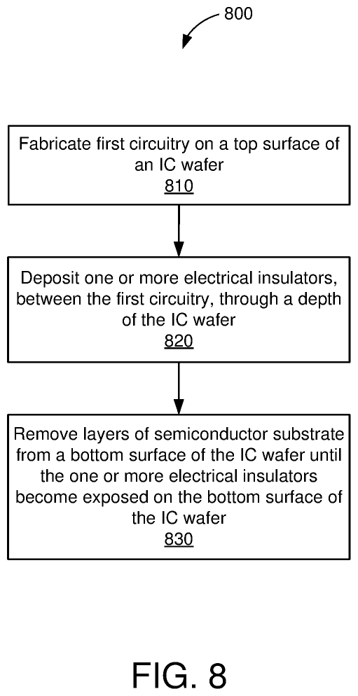

FIG. 8 is an illustrative flowchart depicting an example operation 800 of manufacturing an IC device, in accordance with some embodiments. In some embodiments, the IC device may be a stacked-wafer IC device (e.g., a mixed-signal IC device) including digital circuitry and analog circuitry. With reference for example to FIGS. 4A-4F, the example operation 800 may be used to manufacture the semiconductor wafer according to the various stages 400A-400F depicted.

First circuitry is fabricated on a top surface of an IC wafer (810). In some embodiments, the top surface of the IC wafer may include digital circuitry that is formed on the IC wafer using a first process node. In some other embodiments, the top surface of the second IC wafer may include analog circuitry that is formed on the IC wafer using an analog process node. For example, the digital process node may be smaller or lower-power than the analog process node.

One or more electrical insulators are deposited, between the first circuitry, through a depth of the IC wafer (820). For example, the electrical insulators may be formed by etching respective trenches into the IC wafer and filling the trenches with an oxide material (such as silicon dioxide). In the example of FIG. 4B, the trenches may be etched to a depth below the N-type semiconductor region and into at least a portion of the N+ semiconductor substrate. However, the trenches may not be etched through the entire thickness of the IC wafer (e.g., trenches may not penetrate the bottom surface of the wafer). Thus, the one or more electrical insulators may not be exposed on the bottom surface of the IC wafer.

Layers of semiconductor material are subsequently removed from the bottom surface of the IC wafer until the one or more electrical insulators become exposed on the bottom surface of the IC wafer (830). For example, material or substrate from the bottom surface of the IC wafer may be removed using known backgrinding or chemical mechanical polishing (CMP) techniques. Once exposed, the electrical insulators may electrically isolate various circuit components of the IC wafer. Thus, in some embodiments, the removal of semiconductor material from the bottom surface of the IC wafer may be used to produce (or complete the fabrication of) one or more circuit components of the IC device (e.g., as described above with respect to FIGS. 4A-4F). In some other embodiments, the removal of semiconductor material from the bottom surface of the IC wafer may be used to isolate individual circuit components from one another (e.g., as described above with respect to FIG. 4F).

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the disclosure.

The methods, sequences or algorithms described in connection with the aspects disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

In the foregoing specification, embodiments have been described with reference to specific examples thereof. It will, however, be evident that various modifications and changes may be made thereto without departing from the broader scope of the disclosure as set forth in the appended claims. The specification and drawings are, accordingly, to be regarded in an illustrative sense rather than a restrictive sense.

What is claimed is:

1. A method of manufacturing an integrated circuit (IC) device, comprising:
fabricating first circuitry on a top surface of a first IC wafer;
depositing one or more electrical insulators, between the first circuitry, through a depth of the first IC wafer such that the one or more electrical insulators are not exposed on a bottom surface of the first IC wafer; and
removing layers of semiconductor substrate from a bottom surface of the first IC wafer until the one or more electrical insulators become exposed on the bottom surface of the first IC wafer.

2. The method of claim 1, wherein the layers of semiconductor substrate are removed using backgrinding or chemical mechanical polishing (CMP) techniques.

3. The method of claim 1, wherein one or more circuit components are created on the first IC wafer as a result of removing the layers of semiconductor substrate.

4. The method of claim 1, wherein one or more circuit components are electrically isolated on the first IC wafer as a result of removing the layers of semiconductor substrate.

5. The method of claim 1, further comprising:
aligning the first IC wafer with a second IC wafer, in a stacked configuration, such that the top surface of the first IC wafer faces a top surface of the second IC wafer; and
bonding the first IC wafer with the second IC wafer in the stacked configuration such that the first circuitry disposed on the top surface of the first IC wafer is electrically coupled to second circuitry disposed on the top surface of the second IC wafer.

6. The method of claim 5, wherein, as a result of the bonding, the bottom surface of the first IC wafer forms a top surface of the IC device and the bottom surface of the second IC wafer forms a bottom surface of the IC device.

7. The method of claim 5, wherein the first circuitry is formed on the first IC wafer using a first process node, and wherein the second circuitry is formed on the second IC wafer using a second process node that is different than the first process node.

8. The method of claim 7, wherein the first process node is smaller than the second process node.

9. The method of claim 5, wherein the first circuitry corresponds to digital circuitry and the second circuitry corresponds to analog circuitry.

10. The method of claim 9, wherein the digital circuitry is formed on the first IC wafer using a low-power (LP) or embedded-flash (EF) process, and wherein the analog circuitry is formed on the second IC wafer using a high-voltage (HV) process.

11. The method of claim 2, wherein the removing comprises:
removing the layers of semiconductor substrate until a combined thickness of the first IC wafer and the second IC wafer, in the stacked configuration, is less than or equal to a threshold thickness.

12. The method of claim 11, wherein the threshold thickness corresponds to a thickness of the first IC wafer prior to removing the layers of semiconductor substrate.

13. An integrated circuit (IC) device, comprising:
a first circuit component disposed in a first region of an IC wafer;
a second circuit component disposed in a second region of the IC wafer; and
an electrical insulator deposited between the first region and the second region, the electrical insulator extending from a top surface of the IC wafer to a bottom surface of the IC wafer and electrically isolating the first circuit component from the second circuit component.

14. The IC device of claim 13, wherein at least one of the first or second circuit components comprises a vertical diode having a first terminal provided on the top surface of the IC wafer and a second terminal provided on the bottom surface of the IC wafer.

15. The IC device of claim 13, wherein at least one of the first or second circuit components comprises a via having a first terminal provided on the top surface of the IC wafer and a second terminal provided on the bottom surface of the IC wafer.

16. The IC device of claim 13, wherein at least one of the first or second circuit components comprises a horizontal diode having first and second terminals provided on the top surface of the IC wafer.

17. The IC device of claim 13, wherein at least one of the first or second circuit components comprises a vertical lateral double-diffused metal oxide semiconductor (LDMOS) having a first terminal provided on the top surface of the IC wafer and a second terminal provided on the bottom surface of the IC wafer.

18. The IC device of claim 13, wherein at least one of the first or second circuit components comprises Schottky diode having a first terminal provided on the top surface of the IC wafer and a second terminal provided on the bottom surface of the IC wafer.

19. The IC device of claim 13, wherein at least one of the first or second circuit components comprises a bipolar junction transistor having a first terminal provided on the top surface of the IC wafer and a second terminal provided on the bottom surface of the IC wafer.

20. The IC device of claim 13, wherein the first circuit component comprises a first diode and the second circuit component comprises a second diode, wherein the first diode is coupled in series with the second diode across the top surface or the bottom surface of the IC wafer to form an electrostatic discharge (ESD) diode.
